(19) United States
(12) Patent Application Publication
(10) Pub. No.: US 2005/0258529 A1
(43) Pub. Date: Nov. 24, 2005

(54) High-frequency chip packages

(75) Inventors: Ronald Green, San Jose, CA (US); David B. Tuckerman, Orinda, CA (US); Ron Barnett, Santa Clara, CA (US)

Correspondence Address: LERNER DAVID, LITENBERG, KRUMHOLZ & MENTLIK, 600 SOUTH AVENUE WEST, WESTFIELD, NJ, 07090, US

(73) Assignee: Tessera, Inc., San Jose, CA (US)

(21) Appl. No.: 11/023,826

(22) Filed: Dec. 28, 2004

Related U.S. Application Data
(60) Provisional application No. 60/533,444, filed on Dec. 30, 2003.

(51) Int. Cl. H01L 23/02

(52) U.S. Cl. 257/686

(57) ABSTRACT

A microelectronic package is provided in which a first chip having active elements, e.g. amplifying elements, and passive elements, e.g. resistors, capacitors and inductors, is mounted in electrical communication with a microelectronic element having conductive patterns opposing a front face of the first chip. Absorptive material patterns are disposed between the conductive patterns of the microelectronic element and at least some of the passive elements while leaving at least some of the active elements exposed so as to attenuate radio frequency energy propagated by wave between the passive devices and conductive patterns of the microelectronic element. A packaged chip is also provided in which a chip is disposed beneath a package element, the chip having an opening which extends between a front face and a rear face of the chip, a conductor being disposed in the opening which is conductively connected to a conductive element of the package element.

### CROSS-REFERENCE TO RELATED APPLICATIONS

This application claims the benefit of the filing date of U.S. Provisional Patent Application No. 60/533,444 filed Dec. 30, 2003, the disclosure of which is hereby incorporated herein by reference.

### BACKGROUND OF THE INVENTION

The present invention relates to the art of packaging microelectronic elements such as semiconductor chips.

Chips used for generating or processing radio frequency (“RF”) signals, commonly referred to as “RF chips” are used in wireless devices such as cellular telephones and wireless data communication devices. There have been increasing needs for packages especially suited for use with RF chips with increasing adoption of wireless devices. RF chips typically generate substantial amounts of heat during operation. Moreover, RF chips require low impedance connections within packages and to external circuitry and in some cases require connections capable of handling appreciable electrical current. Moreover, packages for RF chips desirably provide shielding or other means for preventing unwanted propagation of electrical and magnetic fields between the RF chip and the surroundings. For example, a radio frequency power amplifier chip used in a transmitter can generate significant spurious RF emissions.

As the frequencies at which RF chips operate becomes higher, parasitic inductances and capacitances have increased effects upon operation. In particular, the series inductance of a conductor increases directly with frequency. It is desirable to reduce these effects to tolerable levels. However, traditional solutions for lowering parasitic inductances and capacitances do not always agree. Shrinking the lengths of conductive elements while increasing their cross-sectional area lowers series inductance. However, parasitic capacitances increase when the distances between neighboring conductors become smaller and the areas of capacitively coupled conductors increase. It is desirable to package RF chips with microelectronic elements in a way that reduces the coupling of RF energy by wave propagation to and from the chip.

The effects of such parasitics are felt particularly with respect to the distribution of ground and supply voltages within a package. At radio frequencies, even ground and voltage supply connections may not present a stable voltage reference because of such parasitics, particularly parasitic series inductance. At higher radio frequencies, this problem manifests itself in form of ground and power supply references which vary from location to location within a package.

It is desirable to package RF chips in a way that lowers parasitic series inductances such that less variable ground, power supply or other voltage references are provided.

### SUMMARY OF THE INVENTION

Therefore, according to an aspect of the invention, a microelectronic package is provided in which a first chip having active elements, e.g. amplifying elements, and passive elements, e.g. resistors, capacitors and inductors adjacent to a front face of the first chip, is mounted in electrical communication with a microelectronic element having conductive patterns opposing the front face of the first chip. Absorptive material patterns are disposed between the conductive patterns of the microelectronic element and at least some of the passive elements while leaving at least some of the active elements exposed, the absorptive material patterns being adapted to attenuate radio frequency energy propagated by wave between the passive devices and conductive patterns of the microelectronic element.

According to another aspect of the invention, a packaged chip is provided in which a chip is disposed beneath a package element, the chip having a front face, a rear face, and an opening extending between the front face and the rear face thereof, a conductor being disposed in the opening which is conductively connected to a conductive element of the package element.

### BRIEF DESCRIPTION OF THE DRAWINGS

FIG. 1 is a cross-sectional view illustrating a packaged RF chip according to one embodiment of the invention in which absorptive material patterns are provided.

FIG. 2 is a top-down view of an RF chip that is packaged in the embodiment of FIG. 1, the RF chip including a plurality of active and passive devices.

FIG. 3 is a top-down view of the RF chip shown in FIG. 2, as covered by absorptive material patterns according to an embodiment of the invention.

FIG. 4 is a top-down view of the RF chip, as covered by absorptive material patterns according to another embodiment of the invention.

FIG. 5 is a cross-sectional view of a packaged RF chip according to another embodiment of the invention.

FIG. 6 is a bottom-side view of an RF chip for incorporation in a package according to the embodiment of the invention shown in FIG. 5.

FIG. 7 is a cross-sectional view of a packaged RF chip according to a variation of the embodiment shown in FIG. 5.

FIG. 8 is a cross-sectional view of a packaged RF chip according to another variation of the embodiment shown in FIG. 5 in which the RF chip is surface mounted to a circuit panel through an opening in a chip carrier.

FIG. 9 is a cross-sectional view of a packaged RF chip according to yet another variation of the embodiment shown in FIG. 5 in which the RF chip is surface mounted directly to a circuit panel without an intervening chip carrier.

FIG. 10 is a cross-sectional view of a packaged RF chip according to still another variation of the embodiment shown in FIG. 5 in which the RF chip is mounted to a flexible package element in a fold stack package.

### DETAILED DESCRIPTION

According to an embodiment of the invention, an RF absorptive material is disposed between a chip and a microelectronic element of a package as a way of reducing the coupling of RF energy between the chip and the microelectronic element. Materials which absorb radiative RF energy include materials which are lossy due either to their electric or magnetic properties. Many types of materials are lossy at radio frequencies. Dielectrics, especially ferroelectric dielectrics and ferromagnetic materials are among such lossy materials, in addition to resistive materials. Lossy dielectric materials are well suited to such purpose because they can be applied to conductive patterns without requiring an intervening insulating layer.

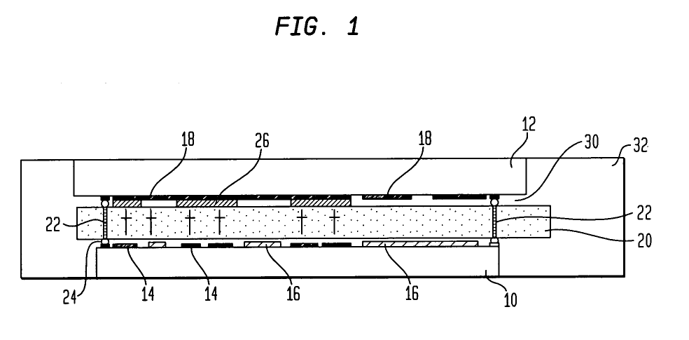

FIG. 1 is a cross-sectional view of a packaged chip according to such embodiment. As shown therein, an RFPA chip 10 is packaged together with a microelectronic element 12 such that device areas 14, 16 of the RFPA chip 10 oppose conductive elements 18 of the microelectronic element. The device areas of the RFPA chip 10 include active devices 16 having a predominant function of amplifying signals and/or modifying signals and passive device areas 14 which do not have amplifying or modifying signals as a predominant function. For example, power amplifier circuits including power transistors, diodes, etc., are among active devices of an RFPA chip. Capacitors, inductors and conductor patterns such as transmission lines which interconnect them are considered passive devices 14. The microelectronic element 12 typically operates cooperatively with the RFPA chip 10. For example, micro-electronic element 12 may have a plurality of passive devices. Examples of microelectronic elements include IPOCs (integrated passives on chip), chips, flexible and rigid chip carriers which include a dielectric element and conductive patterns thereon, ceramic substrates having conductive patterns, lead frames, circuit panels and the like.

As further shown in FIG. 1, a connecting element 20 including a dielectric element is disposed between the RFPA chip 10 and the microelectronic element 12. The RFPA 10 and the microelectronic element 12 are further interconnected by any suitable method, such as those shown and described in commonly owned U.S. patent application Ser. No. 10/746,810, filed Dec. 24, 2003. This application is hereby incorporated by reference herein. In the example shown in FIG. 1, conductive vias 22 extend through the connecting element 20. The vias, in turn, connect the chip 10 to the microelectronic element 12 by way of solder balls 24 disposed on both sides of the connecting element 20. In a variation of this embodiment, the connecting element 20 may include a patterned metal layer on one or both sides of the dielectric element, the dielectric element having openings permitting interconnection to the patterned metal layer from the side of the dielectric opposite the patterned metal layer. An encapsulant 30 including a dielectric material is typically disposed between the microelectronic element 12 and the chip 10, which may also be disposed in a mass 32 surrounding the chip and the microelectronic element. The encapsulant 30 and the dielectric of the connecting element 20 are each typically formed of materials having a dielectric constant k which ranges to a relatively high value, e.g. four, i.e., having a permittivity of about four times the permittivity of free space. In a preferred embodiment, the nominal spacing between the chip 10 and the microelectronic element 12 is about 35 μm.

As further shown in FIG. 1, an absorptive material 26 is disposed between conductive patterns 18 of the microelectronic element 12 and certain devices of the chip 10. The absorptive material is formed as absorptive patterns 26 overlying the conductive patterns 18 of the microelectronic element.

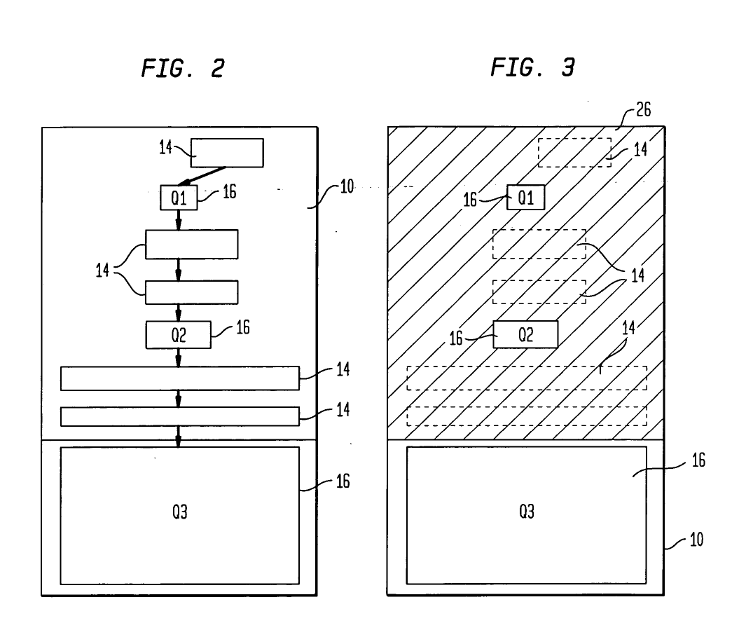

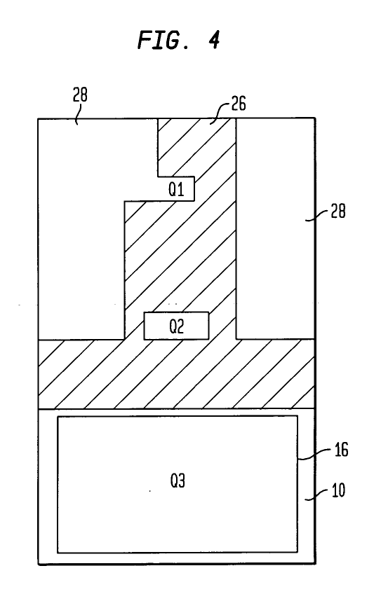

The placement of the absorptive patterns 26 is best shown with reference to FIGS. 2 and 3. FIG. 2 is a top down view illustrating an exemplary placement of devices on the chip 10 including a plurality of active devices 16 and a plurality of passive devices 14. In a particular embodiment, the active devices include successive stages Q1, Q2 and Q3 of an RF power amplifier. Each passive device 14 is an individual element or a network of elements which may include one or more capacitors, such as those used for decoupling and filtering, and may also include one or more inductors, conductive patterns, e.g., transmission lines, etc., in a circuit in which signals are successively amplified by stages Q1 through Q3.

The absorptive patterns 26 are desirably formed of a lossy material having resistive, dielectric, and/or magnetic properties. Polymeric materials having these properties, and other materials having these properties which are suspended in a polymeric material are applied selectively to the microelectronic element 12, as by screening and subsequent curing. Such process results in a thick film cured to a final thickness preferably between about 12 μm and 25 μm. If a thicker layer is required, a second screening of the lossy material can be performed.

FIG. 3 illustrates absorptive patterns 26, as they appear when viewed in a direction looking towards the chip 10, which is shown underlying the absorptive patterns. As shown in FIG. 3, the absorptive patterns 26 extend over the chip 10 to cover areas housing passive devices 14 while exposing the active devices 16. Such placement of absorptive patterns is advantageous. While coupling of radiative RF energy can occur with either passive or active devices, the absorptive patterns affect the operation of each in a different way. In the case of passive devices, the absorptive patterns block signal and noise coupling from the microelectronic element 12 back to the chip 10. However, absorption does not depend on the direction in which the RF energy is being radiated. Thus, at the same time that energy radiated from conductive elements 18 is being absorbed, some energy is being absorbed from signals conducted through the passive devices 14 of the chip 10 which would otherwise have flowed in a direction from Q1 to Q3.

In the case of the active devices 16, it is desirable to avoid attenuating the signals that are being amplified or modified thereby. Therefore, the absorptive patterns 26 are disposed such that they do not overlie some or all of the active devices 16. In such manner, amplification of signals by the chip 10 proceeds with less attenuation of the signal carried by the active devices 16 than if the absorptive patterns were to cover them.

FIG. 4 illustrates another arrangement, similar to that shown in FIG. 3, in which absorptive patterns 26 are disposed in locations which only overlie the passive elements 16 of the chip, leaving all other areas 28 of the chip 10 exposed. Such arrangement can be particularly advantageous when it is desired to avoid further attenuation of signals on the chip 10.

In a variation of the embodiment illustrated in FIG. 1, absorptive patterns, rather than being disposed separately on the surface of the microelectronic element 12, are incorporated into the dielectric layer of the connecting element 20. In such embodiment, the dielectric layer of the connecting element 20 is patterned in the manner shown in FIGS. 3 or 4, such that it is open where the absorptive patterns are open, i.e. areas corresponding to locations of active devices Q1-Q3.

In another variation, the connecting element 20 is omitted such that the chip 10 is surface mounted to the microelectronic element 12, such as by flip-chip attachment using solder balls, the absorptive patterns overlying the microelectronic element 12 and disposed between the chip and the microelectronic element. In another variation, the absorptive patterns are disposed on the chip 10 and the chip is surface mounted to the microelectronic element 12.

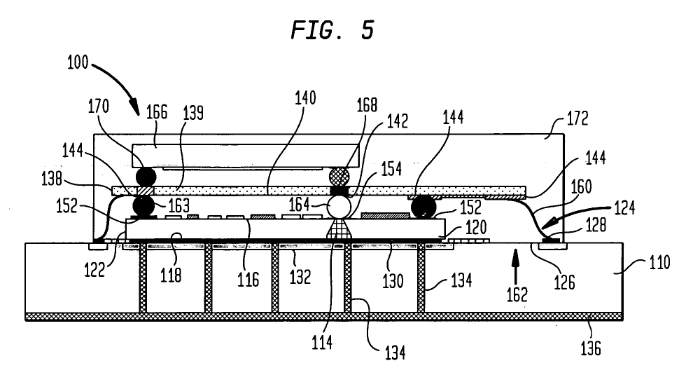

FIG. 5 illustrates an assembly including a package 100 according to another embodiment of the invention, as mounted to a circuit panel 110. In this embodiment, a vertical conductive interconnection between elements of the package is provided through the chip 120.

The chip 120 is desirably designed for radio frequency applications, and preferably is an RFPA having a power amplification function. RFPA chips are typically fabricated in gallium arsenide (GaAs), silicon or silicon germanium (SiGe). As shown in FIG. 5, a chip 120 has a front face 116 and a rear face 118 and peripheral edges 122 extending between the front and rear faces. The chip 120 is mounted to a chip carrier 124, which, in turn, is mounted to the circuit panel 110. The chip carrier is desirably such as that described in the 3.0-342 Application, having a dielectric element 126 and conductive elements disposed either on a top side facing the rear face 118 of the chip, or on a bottom side under the dielectric element. The rear face 118 of the chip 120 is mounted to the circuit panel 110 through a conductive pad 130 of the chip carrier, the chip 120 being attached to the pad 130 by surface mounting through solder or a conductive adhesive, for example. The pad 130 is mounted to the circuit panel 110 by similar means, as described in the incorporated U.S. patent application Ser. No. 10/746,810. The conductive pad 130 is provided as a planar element underlying substantially the entire rear face 118 of the chip 120. The conductive pad 130 is mounted to a conductive pad 132 of the circuit panel 110, which, in turn, is connected by way of vias 134 to a metallized rear surface or “ground plane” 136 which provides a stable source of potential such as ground.

The packaged chip 120 further includes a package element 138 such as those described in the incorporated U.S. patent application Ser. No. 10/746,810, the package element including a conductive plane 140 for distribution of ground or other voltage reference. In the particular embodiment shown in FIG. 5, the package element includes a dielectric element 139 such as a polyimide tape, one or more ground terminals 142 and one or more signal terminals 144 disposed on at least one of the bottom and top sides of the dielectric element 139, and vias extending from the top to the bottom side of the dielectric element 139.

The front face 116 of the chip 120 is mounted to the package element 138 by way of solder balls 163 which extend between signal contacts 152 on the chip 120 and signal terminals 144 of the package element, and solder balls 164 which extend between ground contacts 154 of the chip and ground terminals of the package element.

Signal connections between the circuit panel 110 and the chip 120 are provided through leads such as flex leads 160 shown extending between a terminal 128 of the chip carrier 124 and a corresponding terminal 142 of the connecting element 138. Such leads 160 are provided in the form of leads having frangible sections or cantilevered leads formed integrally to chip carrier 124 or package element 138, for example. The leads 160 are bonded to terminals 128 or terminals 144 through a bonding window 162 in chip carrier 124 when the leads 160 extend from chip carrier 124. Alternatively, leads 160 can include wire bonds extending from terminals 128 to terminals 144. Ground terminals (not shown) can also be provided on the package element 138 and connected to terminals 128 of the chip carrier 124 through such leads 160.

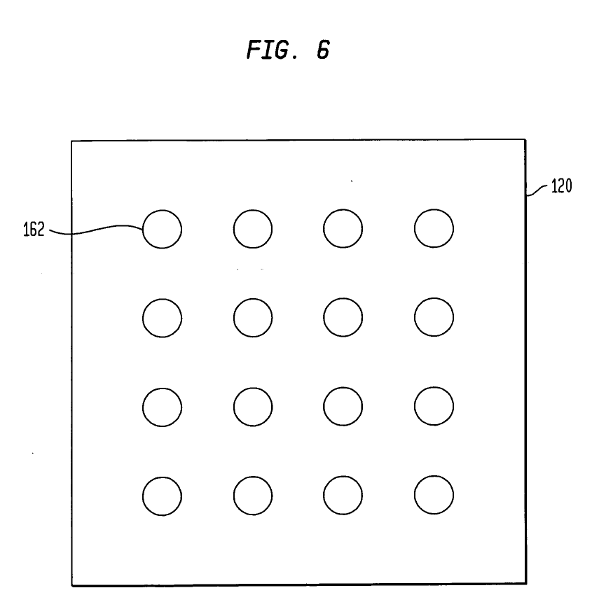

With reference to FIG. 6, low impedance ground connections are provided which extend between the circuit panel 110 through the rear face 118 of the chip to the front face 116 and upward to higher levels of the package 100. Openings 162 are provided in the chip 120 extending between the front and rear faces. Such openings are formed as by etching, drilling or milling, preferably from the rear face 118 of the chip towards the front face. Such openings are sometimes provided in gallium arsenide chips used in high power applications for cooling purposes. According to this embodiment of the invention, some or all of the same openings can be used as ground connections. Conductors are disposed in some or all of the openings, as by lining the opening with a conductive liner. The conductive lining can be any suitable conductor such as a metal and/or a metal compound. In a particular embodiment, layers of tin and gold are provided as the conductive liner. Note that, depending upon the frequency at which the package will be used, it may not be necessary to fill the openings with the conductive material, rather than merely lining them. This is because of the skin effect, in which higher frequency signals tend to be conducted within the uppermost layer of a conductor.

With reference to FIG. 5 again, the conductor 114 is mounted to the conductive pad 130 of the chip carrier 124 at the rear face 118 of the chip. In turn, the conductive pad 130 is connected to the ground plane 136 of the circuit panel through a conductive pad 132 of the circuit panel and vias 134. At the front face 116 of the chip, the conductor 114 is mounted by way of solder ball 164 to a terminal 142 of the package element, which, in turn, is mounted to a further microelectronic element such as an IPOC 166 by another solder ball 168. In such manner, a low impedance conductive interconnection is provided from ground plane 136 upwards through vias 134, conductive pads 130, 132, conductor 114 and solder balls 164, 168 to IPOC 166. As further shown in FIG. 5, IPOC 166 is also connected to signal terminals 144 of the package element 138 through solder ball 170. An encapsulant such as Er=4 is provided covering the chip 120, package element 138 and IPOC 166.

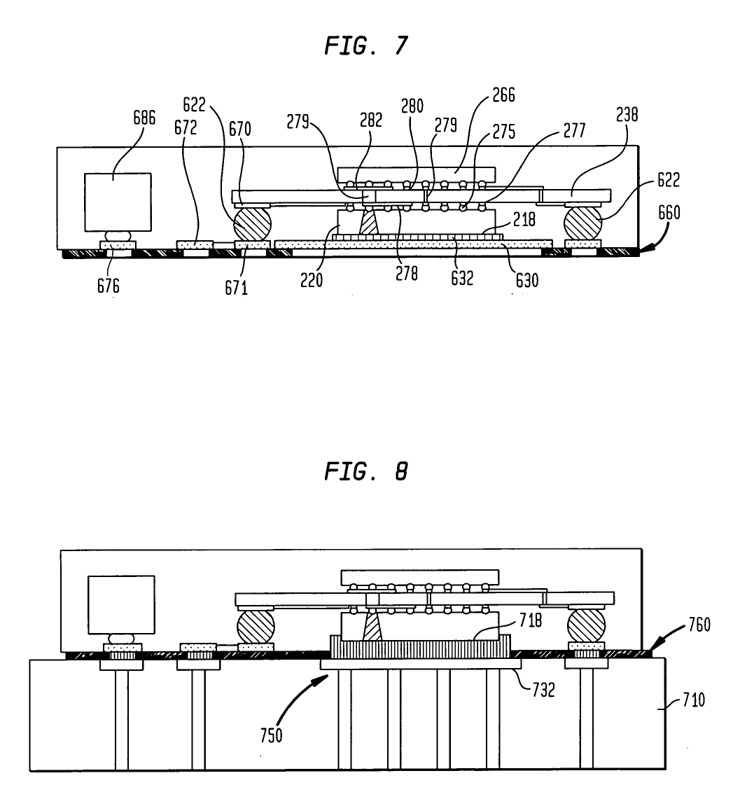

Various modifications can be made to the structure shown in FIG. 5. For example, in a package shown in FIG. 7, the chip 220 is surface mounted to the package element 238 through a series of small solder balls 275 which are connected by way of a lower patterned metallic layer including lands 277 and lower ground trace 278, some of which are connected by way of vias to an upper patterned metallic layer having lands 280 and an upper ground trace 282.

The chip 220 is further mounted to a conductive pad 630 of a lower chip carrier 660 through a solder or conductive adhesive interconnection to the rear face 218 of chip 220.

Large solder balls 622 extend between interconnect terminals 671 and 672, thereby connecting active terminals 672 on the bottom plane element or lower chip carrier 660 and additional component mounting terminals 676 to the connecting element 652 and to chip 220. Some or all of the active terminals 672 may be directly connected by solder balls 622 to interconnect terminals 670 on the connecting element 660. Stated another way, some or all of the active terminals may also serve as interconnect terminals. One or more discrete devices 686, e.g. passive electronic components such as capacitors, resistors and inductors, are bonded to additional element mounting terminals 676 of the lower chip carrier 660, and are connected to chip 220 and/or IPOC 266 through some of the interconnect terminals 670 and 671 and large solder balls 622. In this embodiment, the discrete device 686 is disposed outside of the region covered by the connecting element 238 and projects upwardly to or beyond the level of the connecting element 238. This arrangement allows the package to accommodate relatively thick discrete devices while maintaining a relatively small overall package height.

A further variation is illustrated in FIG. 8 in which bottom package element 760 has an opening 750 disposed below a rear surface of the chip 720, which opening allows the rear surface 718 of the chip to be conductively connected directly to a conductive pad 732 of the circuit panel 710, as by direct solder attachment or conductive adhesive.

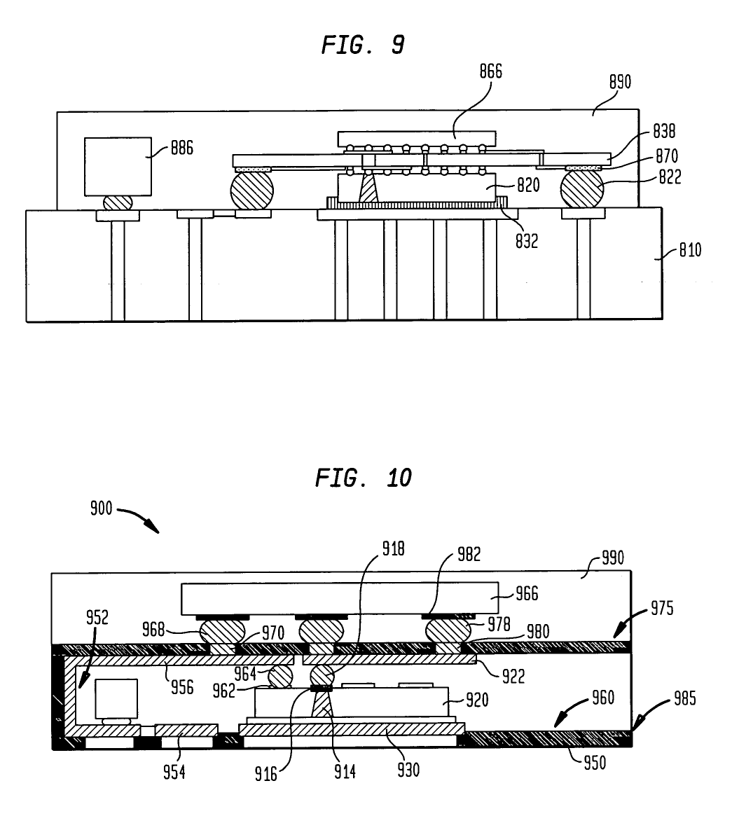

Yet another variation is illustrated in FIG. 9 in which the bottom package element is omitted. In such arrangement, the chip 820 and IPOC 866 are first mounted to the chip carrier 838, while discrete device 886 is mounted to the circuit panel 810. Large solder balls 822 are formed on terminals 870, and the package is then assembled to the circuit panel 810 by way of solder masses 832. An encapsulant 890 can then be applied over the structure.

In yet another variation, shown in FIG. 10, a folded stack package 900 includes a chip 920 mounted to a flexible chip carrier 960 having a flexible dielectric element 950 such as a polyimide tape and a patterned metal layer 952 formed thereon. Such package 900 is similar to that shown and described above with reference to FIG. 7, except as follows. In such package, the patterned metal layer 952 provides signal interconnections from a lower position of signal terminals 954 near the rear face of the chip 920 and signal contacts 962 at the front face of the chip 920 through traces 956 which extend along the surface of the dielectric element 950 and solder balls 964 which are mounted thereto. Signal traces 956 are further connected to an upper microelectronic element 966 such as an upper chip or IPOC through solder balls 968 conductively connected thereto by vias 970. Ground connections can also be provided in similar manner by way of traces of the patterned metal layer.

However, at least some ground connections are provided through conductors 914 which are conductively connected to ground traces or a ground plane 922 of the upper fold 975 by way of solder balls 918. Ground plane 922, in turn, is connected to corresponding ground contacts of the upper microelectronic element 966 by way of ground solder balls and ground vias. The package 900 is optionally covered with an encapsulant 990 which covers the upper fold 975 and elements mounted thereto, as well as being forced into the space between the upper fold and the lower fold 985.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised present without departing from the spirit and scope of the invention as defined by the appended claims.

1. A microelectronic package comprising:
(a) at least one first chip having a front face, and a plurality of active elements and passive elements adjacent to said front face;
(b) at least one microelectronic element in electrical communication with said first chip, said microelectronic element having conductive patterns opposing said front face of said first chip; and
(c) absorptive material patterns disposed between said conductive patterns of said microelectronic element and at least some of said passive elements while leaving at least some of said active elements exposed, said absorptive material patterns adapted to attenuate radio frequency energy propagated by wave between said passive devices of said first chip and said conductive patterns of said microelectronic element.

2. A microelectronic package as claimed in claim 1, wherein said at least one first chip is surface mounted to said at least one microelectronic element.

3. A microelectronic package as claimed in claim 1, wherein said absorptive material patterns include a lossy dielectric material.

4. A microelectronic package as claimed in claim 3, wherein said lossy dielectric material includes a polymeric material having a material suspended therein selected from the group consisting of resistive, dielectric and magnetic materials.

5. A microelectronic package as claimed in claim 1 further comprising a connecting element disposed between said first chip and said microelectronic element, said connecting element including a dielectric element and one or more conductive elements for interconnection of said first chip to said microelectronic element.

6. A microelectronic package as claimed in claim 5, wherein said absorptive material patterns are incorporated in said dielectric element of said connecting element.

7. A microelectronic package as claimed in claim 5, wherein said absorptive material patterns are disposed on a surface of said microelectronic element.

8. A microelectronic package as claimed in claim 5, wherein said absorptive material patterns are disposed on a surface of said first chip.

9. A packaged chip, comprising:
a package element having an upwardly facing top surface, a downwardly facing bottom surface, and a plurality of conductive elements exposed at said bottom surface;
at least one first chip disposed beneath said bottom surface of said package element, said first chip having a front face, a rear face, and peripheral edges extending between said front face and said rear face, said first chip further including an opening extending between said front face and said rear face, and a conductor disposed in said opening between said front face and said rear face and conductively connected to one or more of said conductive elements.

10. A packaged chip as claimed in claim 9, wherein said conductor includes a conductive lining in said opening.

11. A packaged chip as claimed in claim 10, wherein said first chip includes a single-crystal semiconductor region consisting essentially of gallium arsenide (GaAs).

12. A packaged chip as claimed in claim 11, wherein said GaAs chip includes radio frequency circuitry.

13. A packaged chip as claimed in claim 12, wherein said radio frequency circuitry includes a radio frequency power amplifier (RFPA).

14. A packaged chip as claimed in claim 13, wherein said conductive elements include a ground plane extending horizontally in a direction parallel to said bottom surface.

15. A packaged chip as claimed in claim 14, wherein said ground plane is exposed at said bottom surface of said package element.

16. A packaged chip as claimed in claim 15 further comprising solder balls electrically connected to said conductive elements of said package element, wherein a first solder ball of said solder balls conductively connects said conductor to said conductive element of said package element.

17. A packaged chip as claimed in claim 16, wherein said first solder ball conductively connects said conductor to said ground plane.

18. A packaged chip as claimed in claim 17 further comprising leads extending downwardly from said conductive elements of said package element.

19. A packaged chip as claimed in claim 18, wherein said leads extend downwardly to a position in the vicinity of a plane defined by a rear surface of said first chip.

20. A packaged chip as claimed in claim 18, wherein said leads include wire bonds.

21. A packaged chip as claimed in claim 17, wherein a second solder ball of said solder balls conductively connects one conductive element of said conductive elements to a contact on said front surface of said first chip.

22. An assembly including a packaged chip as claimed in claim 15 further comprising a circuit panel disposed below said first chip, wherein said circuit panel is conductively connected to said package element by said conductor.

23. A packaged chip as claimed in claim 9, wherein said package element is a top package element, said packaged chip further comprising a bottom package element disposed below said rear face of said first chip, said bottom package element having an upwardly facing top surface, a downwardly facing bottom surface and conductive elements exposed at at least one of said top surface and said bottom surface.

24. A packaged chip as claimed in claim 23, wherein said conductor conductively connects at least one of said conductive elements of said bottom package element to at least one of said conductive elements of said top package element.

25. A packaged chip as claimed in claim 23, wherein said bottom package element further includes an opening disposed below said rear face of said first chip, wherein said opening is sized and disposed to coincide with a ground connection element of a circuit panel when said packaged semiconductor chip is mounted to the circuit panel to permit said conductor to be conductively connected to the ground connection element.

26. An assembly including a packaged chip as claimed in claim 25, said assembly further including a circuit panel mounted to said bottom surface of said bottom package element, said circuit panel including said ground connection element; and
conductive material conductively connecting said rear surface of said first chip to said ground connection element of said circuit panel.

27. An assembly including a packaged chip as claimed in claim 23, said assembly further including a circuit panel disposed below said bottom package element, said circuit panel providing a conductive ground connection to said conductor.

28. A packaged chip as claimed in claim 16, wherein said package element includes a dielectric layer and said conductive elements include a first conductive via extending through said dielectric layer from said bottom surface to said top surface of said package element, said first conductive via conductively connected to said first solder ball.

29. A packaged chip as claimed in claim 28 further comprising a second chip disposed above said package element, said second chip conductively connected to said bottom surface of said package element through said first conductive via.

30. A packaged chip as claimed in claim 29, wherein said solder balls further include a third solder ball conductively connecting said second chip to said conductive elements of said package element.
